(19) United States
(12) Patent Application Publication
(10) Pub. No.: US 2008/0218209 A1
(43) Pub. Date: Sep. 11, 2008

(54) Device for Controlling Terminal State, Method Thereof, and Device for Transmitting Paging Message

(75) Inventors: Kyoung-Seok Lee, Daejeon (KR); Soo-Jung Jung, Daejeon (KR); Kang-Hee Kim, Daejeon (KR); Soon-Yong Lim, Daejeon (KR); Byung-Han Ryu, Daejeon (KR); Jae-Heung Kim, Daejeon (KR); Jeong-Im Kim, Daejeon (KR); Geon-Min Yeo, Daejeon (KR)

Correspondence Address: CANTOR COLBURN, LLP, 20 Church Street, 22nd Floor, Hartford, CT, 06103, US

(73) Assignee: ELECTRONICS AND TELECOMMUNICATIONS RESEARCH INSTITUTE, DAEJEON (KR)

(21) Appl. No.: 12/064,958

(22) PCT Filed: Aug. 23, 2006
(86) PCT No.: PCT/KR2006/003317

§ 371 Date: Feb. 26, 2008

(30) Foreign Application Priority Data
Aug. 26, 2005 (KR) 10-2005-0078989
Jul. 19, 2006 (KR) 10-2006-0067349

(51) Int. Cl. H03K 19/00

(52) U.S. Cl. 326/56

(57) ABSTRACT

The present invention relates to a device for controlling a state of a terminal with respect to mobility management, and a method thereof. The state of the terminal includes a disconnected state and a connected state, the connected state includes an active state and an idle state, and the active state includes an active sub-state and a standby sub-state. The terminal in the active state updates location information for each cell, and the terminal in the idle state updates the location information for each radio access network registration area including a plurality of cells. The terminal in the active sub-state performs a handover when leaving a current cell. The terminal in the standby sub-state determines a quality of service (QoS) of packet data, and performs the handover or is set to be in the idle state according to the determined QoS.

### TECHNICAL FIELD

The present invention relates to a device for controlling a state of a terminal, a method thereof, and a device for transmitting a paging message. Particularly, the present invention relates to a device for controlling a state of a terminal according to a terminal mobility management function of a 3rd generation partnership project (3GPP) system and a method thereof.

### BACKGROUND ART

In a cellular system, a terminal operates in two operational modes including an idle state for continuously providing a service and conserving power and network resources, and an active state for performing communication between the terminal and a base station. Since a transition between the two operational states is performed by a controlling operation of a radio resource control (RRC) layer in an upper network layer of a protocol configuration, a delay in transmitting a control instruction for the mode transition may occur. Such a control instruction transmitting delay may cause a delay in allocating a shared channel for data transmission and a delay in allocating and recovering a control channel related to channel allocation, in a packet system. In addition, since the channel allocation and recovery operation for the terminal in the active state is performed by the same method, a control physical channel is maintained and power may be problematically consumed when the number of transmission data packets is less and a quality of service (QoS) for the data packet is low. In the prior art, the same delay occurs in performing an initial access and an access for a paging process since a random access process is performed in the same algorithm to perform the initial access and the access for the paging process, and therefore an access operation according to a priority may not be performed.

In addition, in a conventional cellular system, since a mobility management operation is performed for all nodes forming the cellular system, a mobility management process is complicated and overlapping functions are problematically performed.

The above information disclosed in this Background section is only for enhancement of understanding of the background of the invention and therefore it may contain information that does not form the prior art that is already known in this country to a person of ordinary skill in the art.

### DISCLOSURE OF INVENTION

### Technical Problem

The present invention has been made in an effort to provide a device for controlling a state of a terminal according to a mobility management function of the terminal, and a method thereof.

### Technical Solution

In an exemplary method for controlling a state of a terminal according to an embodiment of the present invention, the terminal is set to be in an active state, and the terminal is set to be in an idle state when a quality of service (QoS) required by the terminal in the active state is lower than a predetermined level. In this case, the terminal updates location information for each cell in the active state, and the terminal in the idle state updates the location information for each radio access network registration area (RRA) including a plurality of cells.

The terminal exclusively receives some of shared radio resources and transmits/receives packet data in the active state, and the terminal stops performing synchronization for an uplink traffic channel in the idle state.

In addition, the terminal uses common radio resources to transmit the packet data in the idle state, and uses a discontinuous receiving method for a downlink traffic channel in the idle state.

In an exemplary method for controlling a state of a terminal according to another embodiment of the present invention, the terminal is set to be in an active sub-state, the terminal is set to be in a standby sub-state when a quality of service (QoS) required by the terminal in the active sub-state is lower than a predetermined level, and the terminal is set to be in an idle state when the QoS required by the terminal in the standby sub-state is lower than the predetermined level. The terminal performs a handover when the terminal leaves a current cell in the active sub-state. In the standby sub-state, the terminal determines a QoS of the packet data, performs the handover when the determined QoS is greater than the predetermined level, and is set to be in the idle state when the determined QoS is lower than the predetermined level. In the idle state, the terminal updates location information for each radio access network registration area having a plurality of cells.

An exemplary device for controlling a state of a terminal according to an embodiment of the present invention includes a state controller and a sub-state controller. The state controller controls the terminal to update location information for each cell when setting the terminal to be in an active state, and controls the terminal to update the location information for each radio access network registration area having a plurality of cells when setting the terminal to be in an idle state. The sub-state controller sets the terminal in the active state to be in an active sub-state or in a standby sub-state. In the active sub-state, the terminal performs a handover when the terminal leaves a current cell. In the standby sub-state, the terminal determines a quality of service (QoS) of packet data, performs the handover when the determined QoS is greater than a predetermined level, and is set to be in the idle state when the determined QoS is lower than the predetermined level.

An exemplary device for transmitting a paging message to a first terminal in a first radio access network registration area according to an embodiment of the present invention includes a terminal location management unit and a controller. The terminal location management unit manages location information of a terminal in a plurality of radio access network registration areas having the first radio access network registration area. The controller transmits the paging message to the terminal location management unit when receiving the paging message from an external network. In this case, the terminal location management unit manages a location of the terminal in an active state for each cell, and manages the location of the terminal in an idle state for each radio access network registration area having a plurality of cells. When receiving the paging message for the first terminal in the idle state, the terminal location management unit transmits the paging message along with information on the first radio access network registration area to a plurality of base stations corresponding to the plurality of radio access network registration areas managed by the terminal location management unit so that the plurality of base stations corresponding to the first radio access network registration area transmit the paging message to a radio link.

### ADVANTAGEOUS EFFECTS

According to the exemplary embodiment of the present invention, since the state controlling device controls the transition state of the terminal according to the QoS, and uses various terminal mobility management methods according to the state of the terminal, the radio resources may be efficiently used, power consumption may be reduced, and terminal position management may be easily performed.

### BRIEF DESCRIPTION OF THE DRAWINGS

FIG. 1 shows a schematic view of a cellular system according to an exemplary embodiment of the present invention.

FIG. 2 shows a diagram of a protocol configuration of a state controlling device of the cellular system according to the exemplary embodiment of the present invention.

FIG. 3 shows a state of the terminal managed by the cellular system according to the exemplary embodiment of the present invention.

FIG. 4 shows a block diagram of the state controlling device according to the exemplary embodiment of the present invention.

FIG. 5 shows a block diagram of a GPRS supporting node with respect to paging message transmission according to the exemplary embodiment of the present invention.

### BEST MODE FOR CARRYING OUT THE INVENTION

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

Unless explicitly described to the contrary, the word “comprise” or variations such as “comprises” or “comprising” will be understood to imply the inclusion of stated elements but not the exclusion of any other elements.

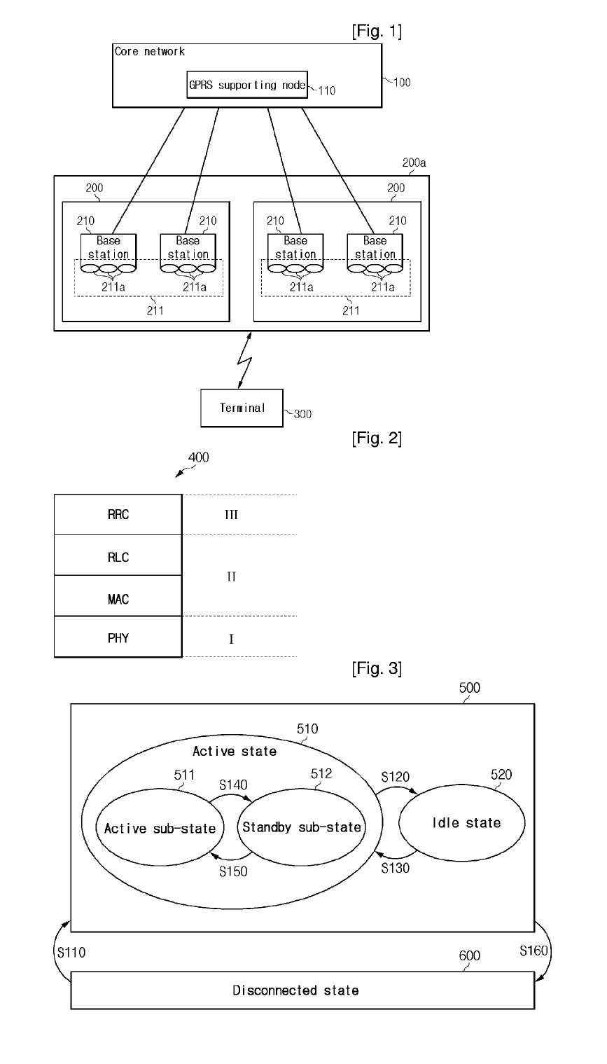

FIG. 1 shows a schematic view of a cellular system according to an exemplary embodiment of the present invention.

As shown in FIG. 1, the cellular system according to the exemplary embodiment of the present invention includes a core network 100 including at least one general packet radio service (GPRS) supporting node 110, and at least one radio network subsystem 200. The radio network subsystems 200 are connected to each other through interfaces to form a radio access network 200a. The radio access network 200a is connected to the core network 100, and the radio network subsystem 200 includes at least one base station 210. The GPRS supporting node 110 supports packet data transformation and transmission, and supports mobility management of a terminal 300. The respective base stations 210 manage at least one cell 211a, and the base stations 210 of each radio network subsystem 200 may be connected through the interfaces. The plurality of cells 211a under control of the at least one base station 210 form a radio access network registration area (RRA, hereinafter, also referred to as a location registration area) 211. The respective base stations 210 or the GPRS supporting node 110 manage information of the cell having the terminal and information of the RRA 211, to manage the mobility of the terminal. The terminal 300 in the cell uses radio resources provided from the corresponding base station 210 to form a radio channel, and is connected to the radio access network 200a through the corresponding base station 210 to perform the data communication.

A protocol configuration of a state controlling device 400 for controlling a state of the terminal according to the exemplary embodiment of the present invention will now be described.

FIG. 2 shows a diagram of the protocol configuration of the state controlling device 400 of the cellular system according to the exemplary embodiment of the present invention. The state controlling device 400 may be formed in the base station 210 of the radio network subsystem 200, and some functions of the state controlling device 400 may be formed in the GPRS supporting node 110.

As shown in FIG. 2, the protocol configuration of the state controlling device 400 according to the exemplary embodiment of the present invention includes a physical layer I, a data link layer II, and a network layer III.

The physical layer I estimates a state of the radio channel, and supports radio transmission techniques of the cellular system. The data link layer II positioned on an upper side of the physical layer I divides and reassembles user data transmitted through the physical layer I, and controls a state of the terminal 300 based on characteristics of a packet service provided by the transmitted data. In addition, the data link layer II includes a media access control layer (hereinafter, referred to as a “MAC layer”) and a radio link control layer. The network layer III sets a wireless bearer to transmit a control instruction and the user data between the terminal 300 and the core network 100. The network layer III includes a radio resource control (RRC) layer. The RRC layer controls an RRC connection that is a path for exchanging control information between the terminal 300 and the core network 100, so as to control a transition operation of the two operational modes of the terminal 300.

FIG. 3 shows a state of the terminal managed by the cellular system according to the exemplary embodiment of the present invention.

As shown in FIG. 3, the state of the terminal according to the exemplary embodiment of the present invention includes a connected state 500 and a disconnected state 600.

When the terminal 300 is in the disconnected state 600, the GPRS supporting node 110 of the core network 100 has no location information for a mobility management function including location and handover control functions of the terminal 300, and no routing information for a routing control operation for transmitting data of the terminal. Accordingly, it is required to set the radio connection for exchanging information and packet data so as to provide various packet services to the terminal 300 in the disconnected state 600. A packet data protocol (PDP) context including various pieces of information required to transmit user data traffic is set between the GPRS supporting node 110, the base station 210, and the terminal 300 controlled to be in the connected state 500 through the radio connection.

In the connected state 500, the RRC connection is formed through the RRC layer of the state controlling device 400, control instruction signals are exchanged through the RRC connection, and data are transmitted through a physical channel allocated to the terminal 300 exclusively or in common. That is, in the connected state 500, the PDP context for transmitting the data traffic between the terminal 300, the base station 210, and the GPRS supporting node 110 is set, and the terminal 300 is accessed to the GPRS supporting node 110. The location information of the terminal 300 in the connected state 500 may be managed for each RRA 211 or each cell 211a.

The connected state 500 includes an active state 510 and an idle state 520.

The terminal 300 in the idle state 520 uses common radio resources managed by the base station 210 to transmit the packet data. The common radio resources are shared by the plurality of terminals 300, and the respective terminals preoccupy the base station to use the common radio resources. As examples of the common radio resources, there are a random access channel and a paging message transmission channel. Since the terminal 300 in the idle state 520 performs a paging cycle operation so that a receipt operation is performed only during a paging channel receiving cycle, power consumption may be reduced. That is, the base station uses the paging channel to manage the mobility of the terminal in the idle state 520. When the base station has information to be provided to the terminal 300 in the idle state 520, the information is transmitted through the paging channel. To reduce the power consumption caused by the terminal receiving a base station signal, the paging channel has the paging channel receiving cycle to be allocated to the terminal 300, and the terminal 300 may stop performing the receiving operation while the paging message is not received. The terminal 300 in the idle state 520 stops an uplink synchronization operation and may further reduce the power consumption. In addition, the terminal 300 in the idle state 520 may use a discontinuous receiving method (hereinafter, referred to as a “DRX” method) to further reduce the power consumption. That is, the terminal 300 in the idle state 520 stops a synchronization maintenance operation for an uplink traffic channel, and uses the DRX method for a downlink traffic channel. The transition from the idle state 520 to the active state 510 is performed in a contention-based random access process. When all the packet service sessions for the terminal are finished, the state controlling device 400 controls the terminal 300 to be in the idle state 520. The GPRS supporting node 110 allocates an identifier (hereinafter, referred to as an “ID”) identified in the RRA 211 including the terminal 300 to the terminal 300 in the idle state 520, controls the mobility and the common radio resources based on the allocated ID, and performs the mobility managing operation for each RRA 211. An RRA update operation is performed when the terminal 300 in the idle state 520 leaves the current RRA 211. That is, the terminal 300 in the idle state 520 updates the location information managed by the GPRS supporting node 110, for each RRA. In addition, the GPRS supporting node 110 stores RRC connection information for the terminal 300 in the idle state 520, and provides the RRC connection information to the terminal 300 controlled to be in the active state 510 so that the terminal is quickly set to be in the active state 510.

The terminal 300 in the active state 510 exclusively receives some resources among shared radio resources to transmit/receive the packet data. In addition, when leaving the current cell, the terminal 300 in the active state 510 performs a cell update operation. That is, the terminal 300 in the active state 510 updates the location information for each cell. An identifier identified in the corresponding cell 211a may be allocated to the terminal 300 in the active state 510, and the cellular system performs the mobility management operation for each cell 211a based on the allocated identifier. In addition, the identifier for each RRA may be further allocated to the terminal 300 in the active state 510.

The active state 510 may be divided into an active sub-state 511 and a standby sub-state 512 according to an occupying state of the radio resources according to a controlling operation of the data link layer II.

In the active sub-state 511, the packet services are continuously provided to the terminal 300, and the terminal 300 is under control of a scheduler (not shown) for managing the radio resources in the MAC layer. In addition, in the active sub-state 511, a measurement channel for analyzing radio environment qualities including traffic volume and channel quality and providing an analyzed result is activated to perform a scheduling operation for the terminal 300. That is, the base station 210 estimates a quality of service (QoS) required by the terminal 300 in the active sub-state 511 through the measurement channel, and exclusively allocates some of the shared radio resources to the terminal according to the estimated QoS. In addition, since the packet data are continuously transmitted/received in the active sub-state 511 between the base station 210 and the terminal 300, the terminal 300 in the active sub-state 512 performs a handover operation when leaving the current cell.

In the standby sub-state 512, the amount of the transmitted/received packet data between the base station 210 and the terminal 300 is less than a predetermined level, the terminal 300 in the standby sub-state 512 is exempt from the scheduling operation, and the measurement channel is deactivated. The base station 210 uses a control channel and a data channel for the terminal 300 in the standby sub-state 512 in a discontinuous transmission (DTX) method or in the discontinuous receipt (DRX) method. The terminal 300 in the standby sub-state 512 may be used as an intermediate step so that the terminal 300 may pass through the standby sub-state 512 when a state of the terminal 300 is changed from the active state 510 to the idle state 520. In addition, the terminal 300 in the standby sub-state 512 determines the QoS of the packet data, and performs the handover when the determined QoS is greater than a predetermined level. However, the terminal 300 in the standby sub-state 512 requests a transition to the idle state 520, to the state controlling device 400. As described, since the cellular system uses the active sub-state 511 and the standby sub-state 512 to operate the terminal 300, resources that are appropriate for the packet service provided to the terminal 300 may be allocated, and the power consumption of the terminal may be reduced.

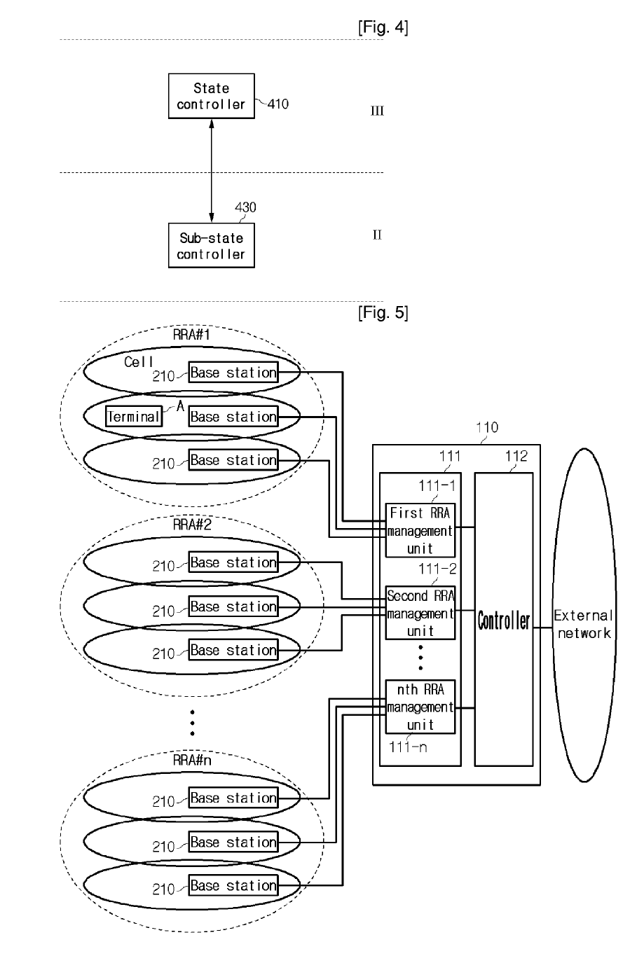

The state controlling device 400 according to the exemplary embodiment of the present invention will now be described with reference to FIG. 4.

FIG. 4 shows a block diagram of the state controlling device 400 according to the exemplary embodiment of the present invention.

As shown in FIG. 4, the state controlling device 400 includes a state controller 410 in the network layer III, and a sub-state controller 430 in the data link layer II.

The state controller 410 sets the terminal 300 to be in the connected state 500 or in the disconnected state 600, and sets the terminal 300 in the connected state 500 to be in the active state 510 or in the idle state 520. The sub-state controller 430 sets the terminal 300 in the active state 510 to be in the active sub-state 511 or in the standby sub-state 512.

The state controller 410 allocates the shared radio resources to the terminal 300 in the active state 510, and the sub-state controller 430 measures the QoS required by the terminal 300 in the active sub-state 511 through the measurement channel and exclusively allocates some of the shared radio resources to the terminal 300 according to the measured QoS. The sub-state controller 430 deactivates the measurement channel for the terminal 300 in the standby sub-state 512. In addition, the sub-state controller 430 may uses the control channel and the data channel for the terminal 300 in the standby sub-state 512 in the DTX method or in the DRX method.

The state controller 410 controls the terminal 300 in the idle state 520 to stop performing the uplink traffic channel synchronization, and allocates the common radio resources to the terminal 300 in the idle state 520. In addition, the state controller 410 uses the downlink traffic channel set to the terminal 300 in the idle state 520, in the discontinuous DRX method.

A state controlling method according to the exemplary embodiment of the present invention will be described with reference to FIG. 3 and FIG. 4.

The state controller 410 sets the terminal 300 to be in the connected state 500 in step S110 when a radio access is formed between the terminal 300 and the base station 210. In this case, the state controller 410 may set the terminal 300 to be in the active state 510 or in the idle state 520.

In addition, the state controller 410 sets the terminal 300 to be in the idle state 520 in step S120 when the QoS required by the terminal 300 in the active state 510 is lower than a predetermined level, and sets the terminal 300 to be in the active state 510 in step S130 when the QoS required by the terminal 300 in the idle state 520 is greater than a predetermined level. The state controller 410 may set the terminal 300 to be in the active state 510 in step S130 when receiving a request for setting the terminal 300 to be in the active state 510 from the terminal 300 in the idle state 520 through the common radio resource or the random access channel. When the state controller 410 sets the terminal 300 to be in the active state 510 in step S130, the sub-state controller 430 may set the terminal 300 to be in the active sub-state 511 or in the standby sub-state 512.

The sub-state controller 430 sets the terminal 300 to be in the standby sub-state 512 in step S140 when the QoS required by the terminal 300 in the active sub-state 511 is lower than the predetermined level, and sets the terminal 300 to be in the active sub-state 511 in step S150 when the QoS required by the terminal 300 in the standby sub-state 512 is greater than the predetermined level. The sub-state controller 430 may set the terminal 300 to be in the active sub-state 511 in step S150 when receiving a request for setting the terminal 300 to be in the active sub-state 511 from the terminal 300 in the standby sub-state 512.

In addition, the state controller 410 sets the terminal to be in the disconnected state 600 in step S160 when the radio access is finished between the terminal and the base station 210.

The GPRS supporting node 110 with respect to paging message transmission will be described with reference to FIG. 5.

FIG. 5 shows a block diagram of the GPRS supporting node 110 with respect to paging message transmission according to the exemplary embodiment of the present invention.

As shown in FIG. 5, the GPRS supporting node 110 includes a terminal location management unit 111 and a controller 112.

The terminal location management unit 111 manages the location information of the terminal in the plurality of radio access network registration areas RRA #1 to RRA #n.

More particularly, the terminal location management unit 111 has the location information of the terminal 300 in the active state 510 for each cell, and allocates the identifier identified in the cell having the corresponding terminal 300 to the terminal 300. In addition, the terminal location management unit 111 has the location information for each RRA including the terminal 300 in the active state 510, and further allocates the identifier identified in the RRA having the corresponding terminal 300 to the terminal 30. Further, the terminal location management unit 111 has the location information of the terminal 300 in the idle state 520 for each RRA, and allocates the identifier identified in the RRA having the corresponding the terminal 300 to the terminal 300.

The terminal location management unit 111 according to the exemplary embodiment of the present invention includes a plurality of RRA management units 111-1 to 111-n. The plurality of RRA management units 111-1 to 111-n respectively correspond to the plurality of RRAs RRA #1 to RRA #n, and manage the location information of the terminal in the corresponding RRA.

A method for transmitting the paging message to the terminal A in the idle state 520 by the GPRS supporting node 110 will be described. In this case, it is assumed that the terminal A is positioned in a first RRA RRA #1.

The controller 112 transmits a received paging message to the terminal location management unit 111 when receiving the paging message relating to the terminal A from an external network. Then, the terminal location management unit 111 transmits the paging message to the plurality of base stations 210 corresponding to the plurality of RRAs RRA #1 to RRA #n. In this case, the terminal location management unit 111 transmits information on the RRA RRA #1 where the terminal A is positioned. The base station 210 receiving the paging message analyzes the transmitted information on the RRA and transmits the received paging message to a radio link when the base station 210 is in the RRA including the terminal A. That is, the plurality of base stations 210 corresponding to the first RRA RRA #1 transmits the received paging message to the radio link so that the terminal A receives the corresponding paging message.

Since the function relating to the paging operation is eliminated from the GPRS supporting node 110, the function of the GPRS supporting node 110 may be simplified.

In addition, when an Internet protocol (IP)-based backbone network is used between the GPRS supporting node 110 and the base station 210, the paging message may be transmitted to the base stations 210 corresponding to the plurality of RRAs managed by the GPRS supporting node 110 without increasing additional traffic since the GPRS supporting node 110 transmits the paging message through a multicasting address.

As described, the GPRS supporting node 110 may receive a response to the paging message from the corresponding terminal 300 without allocating the identifier for each cell to the terminal 300 in the idle state 520. Accordingly, the identifier for each cell may be efficiently used. In addition, the GPRS supporting node 110 is not required to update the location information to receive the response to the paging message from the terminal 300 in the idle state 520.

The above-described methods and apparatuses are not only realized by the exemplary embodiment of the present invention, but, on the contrary, are intended to be realized by a program for realizing functions corresponding to the configuration of the exemplary embodiment of the present invention or a recording medium for recording the program.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A method for controlling a state of a terminal, the method comprising:
setting the terminal to be in an active state; and
setting the terminal to be in an idle state when a quality of service (QoS) required by the terminal in the active state is lower than a predetermined level,
wherein the terminal updates location information for each cell in the active state, and the terminal in the idle state updates the location information for each radio access network registration area (RRA) including a plurality of cells.

2. The method of claim 1, wherein the terminal receives some resources among shared radio resources and transmits/receives packet data in the active state, and the terminal stops performing synchronization for an uplink traffic channel in the idle state.

3. The method of claim 2, wherein the terminal uses common radio resources to transmit the packet data in the idle state.

4. The method of claim 3, wherein the terminal uses a discontinuous receiving method for a downlink traffic channel in the idle state.

5. The method of claim 4, wherein the setting of the terminal to be in the active state comprises
setting the terminal to be in the active state when the QoS required by the terminal in the idle state is greater than the predetermined level.

6. The method of claim 4, wherein the setting of the terminal to be in the active state comprises
setting the terminal to be in the active state when receiving a request for setting the terminal to be in the active state from the terminal in the idle state through the common radio resources.

7. The method of claim 2, wherein the active state comprises:
an active sub-state in which the terminal performs a handover when the terminal leaves a current cell; and
a standby sub-state in which the terminal determines a QoS of the packet data and performs a handover when the determined QoS of the data packet is greater than a predetermined level, and is set to be in the idle state when the determined QoS is lower than the predetermined level.

8. The method of claim 7, wherein, in the active sub-state, the QoS required by the terminal is measured through a measurement channel, and some resources among the shared radio resources are allocated to the terminal according to the measured QoS.

9. The method of claim 8, wherein the measurement channel is deactivated in the standby sub-state.

10. The method of claim 7, further comprising
setting the terminal to be in the standby sub-state when the QoS required by the terminal in the active sub-state is lower than the predetermined level.

11. The method of claim 10, further comprising
setting the terminal to be in the active sub-state when the terminal in the standby sub-state requires a QoS that is greater than the predetermined level.

12. The method of claim 10, further comprising
setting the terminal to be in the active sub-state when receiving a request for setting the terminal to be in the active sub-state from the terminal in the standby sub-state.

13. A method for controlling a state of a terminal, the method comprising:
setting the terminal to be in an active sub-state;
setting the terminal to be in a standby sub-state when a quality of service (QoS) required by the terminal in the active sub-state is lower than a predetermined level;
setting the terminal to be in an idle state when the QoS required by the terminal in the standby sub-state is lower than the predetermined level,
wherein, in the active sub-state, the terminal performs a handover when the terminal leaves a current cell,
in the standby sub-state, the terminal determines a QoS of the packet data and performs a handover when the determined QoS is greater than the predetermined level, and is set to be in the idle state when the determined QoS is lower than the predetermined level, and
in the idle state, the terminal updates location information for each radio access network registration area having a plurality of cells.

14. The method of claim 13, wherein:
in the active sub-state, the QoS required by the terminal is measured through a measurement channel, and some resources among shared radio resources are allocated to the terminal according to the measured QoS;
in the standby sub-state, the measurement channel is deactivated; and
in the idle state, the terminal stops synchronization for an uplink traffic channel.

15. The method of claim 14, wherein common radio resources are allocated to the terminal in the idle state, and the setting the state of the terminal to be in the active sub-state comprises setting the terminal to be in the active sub-state when receiving a request for setting the terminal to be in the active sub-state from the terminal in the idle state through the common radio resources.

16. The method of claim 15, wherein the setting of the terminal to be in the active sub-state comprises
setting the terminal to be in the active sub-state when the terminal requires the QoS that is greater than the predetermined level.

17. A device for controlling a state of a terminal, the device comprising:
a state controller for controlling the terminal to update location information for each cell when setting the terminal to be in an active state, and controlling the terminal to update the location information for each radio access network registration area having a plurality of cells when setting the terminal to be in an idle state; and
a sub-state controller for setting the terminal in the active state to be in an active sub-state or in a standby sub-state,
wherein, in the active sub-state, the terminal performs a handover when the terminal leaves a current cell, and
in the standby sub-state, the terminal determines a quality of service (QoS) of packet data and performs the handover when the determined QoS is greater than a predetermined level, and is set to be in the idle state when the determined QoS is lower than the predetermined level.

18. The device of claim 17, wherein the state controller allocates shared radio resources to the terminal in the active state.

19. The device of claim 18, wherein the sub-state controller measures a QoS required by the terminal in the active sub-state through a measurement channel, and allocates some resources among the shared radio resources to the terminal according to the measured QoS.

20. The device of claim 19, wherein the sub-state controller deactivates the measurement channel for the terminal in the standby sub-state.

21. The device of claim 20, wherein the state controller controls the terminal in the idle state to stop synchronization for an uplink traffic channel.

22. The device of claim 21, wherein the state controller allocates common radio resources to the terminal in the idle state.

23. The device of claim 22, wherein the state controller uses a downlink traffic channel set for the terminal in the idle state, in a discontinuous receiving method.

24. The device of claim 17, wherein the state controller sets the terminal to be in the idle state when the QoS required by the terminal in the active state is lower than the predetermined level.

25. The device of claim 24, wherein the state controller sets the terminal to be in the active state when the QoS required by the terminal in the idle state is greater than the predetermined level.

26. The device of claim 25, wherein the sub-state controller sets the terminal to be in the standby sub-state when the QoS required by the terminal in the active state is lower than the predetermined level.

27. The device of claim 26, wherein the sub-state controller sets the terminal to be in the active sub-state when the QoS required by the terminal in the standby sub-state is greater than the predetermined level.

28. A device for transmitting a paging message to a first terminal in a first radio access network registration area, the device comprising:
a terminal location management unit for managing location information of a terminal in a plurality of radio access network registration areas having the first radio access network registration area; and
a controller for transmitting the paging message to the terminal location management unit when receiving the paging message from an external network,
wherein the terminal location management unit manages a location of the terminal in an active state for each cell and manages the location of the terminal in an idle state for each radio access network registration area having a plurality of cells, and
when receiving the paging message for the first terminal in the idle state, the terminal location management unit transmits the paging message along with information on the first radio access network registration area to a plurality of base stations corresponding to the plurality of radio access network registration areas managed by the terminal location management unit so that the plurality of base stations corresponding to the first radio access network registration area transmit the paging message to a radio link.

29. The device of claim 28, wherein the terminal location management unit transmits the paging message to the plurality of base stations corresponding to the plurality of radio access network registration areas managed by the terminal location management unit, through a multicasting address.
